(19) United States
(12) Patent Application Publication
(10) Pub. No.: US 2024/0038569 A1
(43) Pub. Date: Feb. 1, 2024

(54) MICRO DEVICE, MICRO DEVICE ALIGNMENT APPARATUS, AND ALIGNMENT METHOD USING SAME

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Jeong Hyuk LEE, Gyeonggi-do (KR)

(73) Assignee: POINT ENGINEERING CO., LTD., Chungcheongnam-do (KR)

(21) Appl. No.: 18/037,081

(22) PCT Filed: Dec. 8, 2021
(86) PCT No.: PCT/KR2021/018518

§ 371 Date: May 16, 2023

(30) Foreign Application Priority Data
Dec. 9, 2020 (KR) 10-2020-0171490

(51) Int. Cl. H01L 21/683

(52) U.S. Cl. CPC H01L 21/6835; H01L 2221/68354; H01L 2221/68322

(57) ABSTRACT

A micro device, a micro device alignment apparatus, and an alignment method using the same are proposed. In a micro device that has to be aligned with at least any one surface of front and rear surfaces of the micro device when mounted on a substrate and simultaneously be aligned with any one direction of the micro device when mounted on the substrate, there is provided the micro device, the micro device alignment apparatus, and the alignment method using the same so that surface alignment and direction alignment are simultaneously performed for a plurality of micro devices that is not aligned with at least any one surface of the front and rear surfaces and simultaneously is not aligned with any one direction.

### TECHNICAL FIELD

The present disclosure relates to a micro device, a micro device alignment apparatus, and an alignment method using the same.

### BACKGROUND ART

Currently, while LCDs dominate in the display market, OLEDs are rapidly replacing LCDs and emerging as mainstream products. In a current situation where display makers are in a rush to participate in the OLED market, micro light-emitting diode (hereinafter referred to as “micro LED”) displays have emerged as another next-generation display. Liquid crystal and organic materials are respectively the core materials of LCDs and OLEDs, whereas the micro LED display uses an LED chip itself in a size of 1 to 100 micrometers (μm) as a light-emitting material.

In a micro device such as the micro LED, a transfer process may be performed in order for the micro device to be manufactured on a growth substrate and transferred to a substrate (e.g., a carrier substrate, a temporary substrate, or a circuit substrate).

In the related art, as a transfer method for transferring micro devices manufactured on the growth substrate, the transfer method using a transfer head is considered, wherein the micro devices are adsorbed by the transfer head and transferred to the substrate (e.g., the carrier substrate, temporary substrate, or circuit substrate). However, the head transfer method has a difficulty in reliably transferring each micro device in a unit of 1 to 100 micrometers (μm), and has a difficulty in improving production rate due to taking time for repairing transfer errors.

Accordingly, in order to improve the production rate, a fluid transfer method for transferring micro devices to a substrate (e.g., the carrier substrate, temporary substrate, or circuit substrate) by using a fluid has been considered. In the fluid transfer method, there is provided an advantage that the production rate may be improved in terms of being able to transfer a large number of micro devices to the substrate all together at once, but there is a high probability that the micro devices having the top and bottom surfaces thereof turned upside down are transferred to the substrate, so it takes a lot of time to correctly align the micro devices having the top and bottom surfaces thereof turned upside down after the fluid transfer. In addition, even when the top and bottom surfaces of the micro devices are correctly aligned, since each flip chip type micro device has two terminals on one surface thereof, there is a high probability that the directionality of the two terminals is not properly aligned.

As such, the transfer method in the related art has the advantage of being able to respectively receive the micro devices all together at once in predetermined recesses in order to transfer the micro devices, but has the problem that the alignment error of the micro devices is high.

### DOCUMENTS OF RELATED ART

(Patent Document 1) U.S. Pat. No. 9,722,145
(Patent Document 2) U.S. Pat. No. 9,892,944
(Patent Document 3) U.S. Pat. No. 9,917,226
(Patent Document 4) U.S. Patent Application Publication No. 2018-0076168
(Patent Document 5) U.S. Patent Application Publication No. 2018-0076068
(Patent Document 6) U.S. Patent Application Publication No. 2018-0033915

### DISCLOSURE OF INVENTION

### Technical Problem

The present disclosure has been devised to solve the problems of the related art described above. In micro devices that has to be aligned with at least any one surface of front and rear surfaces of the micro device when mounted on a substrate and simultaneously be aligned with any one direction of the micro device when mounted on the substrate, an objective of the present disclosure is to provide a micro device, a micro device alignment apparatus, and an alignment method using the same, wherein surface alignment and direction alignment are simultaneously performed for a plurality of micro devices that is not aligned with at least any one surface of the front and rear surfaces and simultaneously is not aligned with any one direction.

### Solution to Problem

In order to achieve such an objective of the present disclosure, there is provided a micro device that has to be aligned with at least any one surface of front and rear surfaces of the micro device when mounted on a substrate and simultaneously be aligned with any one direction of the micro device when mounted on the substrate, the micro device including top view shapes thereof, wherein each top view shape thereof before and after inversion of the front and rear surfaces thereof is not a same shape identical to each other, and simultaneously, each top view shape thereof before and after rotation when rotated 180 degree angles relative to a center point of the micro device is not the same shape identical to each other.

Meanwhile, there is provided a micro device that has to be aligned with at least any one surface of front and rear surfaces of the micro device when mounted on a substrate and simultaneously be aligned with any one direction of the micro device when mounted on the substrate, the micro device including: a top view shape thereof, wherein the top view shape of the micro device is not an overlapping shape when folded along an axis of symmetry thereof, and simultaneously the top view shape of the micro device is not an overlapping shape when rotated 180 degree angles relative to a center point thereof.

Meanwhile, there is provided a micro device that has to be aligned with at least any one surface of front and rear surfaces of the micro device when mounted on a substrate and simultaneously be aligned with any one direction of the micro device when mounted on the substrate, the micro device including: a top view shape thereof, wherein the top view shape of the micro device is not a line-symmetrical shape, and simultaneously the top view shape of the micro device is not a point-symmetrical shape.

In addition, the micro device may be a light-emitting device comprising both of two terminals thereof provided on any one surface of the front and rear surfaces of the micro device.

Meanwhile, in order to achieve the objective of the present disclosure, there is provided a micro device alignment apparatus including an alignment part provided with a plurality of receiving parts configured to respectively receive a plurality of micro devices, wherein each receiving part is formed in a same shape as a top view shape of the micro device, and the top view shape of each receiving part is configured not to be an overlapping shape when folded along an axis of symmetry thereof, and simultaneously the top view shape of each receiving part is configured not to be an overlapping shape when rotated 180 degree angles relative to a center point thereof.

In addition, the alignment part may be composed of an anodized film formed by anodizing a metal.

In addition, the alignment part may be provided in a picker head capable of ascending and descending.

In addition, the alignment part may be provided to be movable relative to a temporary substrate.

In addition, each micro device may be a light-emitting device comprising both of two terminals provided on any one surface of front and rear surfaces of each micro device.

Meanwhile, in order to achieve the objective of the present disclosure, there is provided a micro device alignment apparatus including an alignment part provided with a plurality of receiving parts configured to respectively receive a plurality of micro devices, wherein each receiving part is formed in a same shape as top view shapes of each micro device, and in each micro device, each top view shape thereof before and after inversion of the front and rear surfaces thereof is not the same shape identical to each other, and simultaneously, each top view shape thereof before and after rotation when rotated 180 degree angles relative to a center point of each micro device is not the same shape identical to each other.

Meanwhile, in order to achieve the objective of the present disclosure, there is provided a micro device alignment apparatus configured to perform surface alignment and direction alignment for a plurality of micro devices not aligned with at least any one surface of front and rear surfaces and simultaneously not aligned with any one direction, the micro device alignment apparatus including: an alignment part provided with a plurality of receiving parts configured to respectively receive a plurality of micro devices, wherein the micro devices respectively received in the receiving parts are aligned with at least any one surface of the front and rear surfaces thereof, and simultaneously directions of terminals of each micro device are aligned in any one direction.

In addition, in each micro device, each top view shape of the micro device before and after inversion of the front and rear surfaces thereof may be not a same shape identical to each other, and simultaneously, each top view shape of the micro device before and after rotation when rotated 180 degree angles relative to a center point of each micro device may be not the same shape identical to each other.

In addition, one of the front and rear surfaces of the micro device may be either a surface on which the terminals of each micro device are provided or a surface opposite to the surface.

Meanwhile, in order to achieve the objective of the present disclosure, there is provided a micro device alignment method including: preparing a plurality of micro devices, in a non-aligned state, that is not aligned with at least any one surface of front and rear surfaces and simultaneously is not aligned in any one direction; and allowing the micro devices to be respectively received in receiving parts by using an alignment part provided with a plurality of receiving parts capable of respectively receiving the plurality of micro devices, and performing surface alignment and direction alignment wherein the micro devices respectively received in the receiving parts are aligned with at least any one surface of the front surface and the rear surface of each micro device and simultaneously directions of the micro devices are aligned with any one direction of each micro device.

In addition, the preparing of the plurality of micro devices in the non-aligned state may be a step of comprising only good quality micro devices.

### Advantageous Effects of Invention

The micro device, the micro device alignment apparatus, and the alignment method using the same according to the present disclosure has an effect that the surface alignment and direction alignment are simultaneously performed for the plurality of micro devices that is not aligned with at least any one surface of the front and rear surfaces thereof and simultaneously is not aligned with any one direction.

### BRIEF DESCRIPTION OF DRAWINGS

FIG. 1 is a view illustrating a micro device alignment apparatus according to a preferred exemplary embodiment of the present disclosure.

FIG. 2 is a view illustrating an alignment part according to the preferred exemplary embodiment of the present disclosure.

FIG. 3(a) to 3(c) is a view illustrating a micro device according to the preferred exemplary embodiment of the present disclosure.

FIG. 4 is a view illustrating that micro devices are respectively received in at least a portion of receiving parts of the alignment part according to the preferred exemplary embodiment of the present disclosure or the micro devices are not respectively received in the remaining portion of the receiving parts.

FIGS. 5(a) to 6(f) are views illustrating various top view shapes of the micro devices.

FIGS. 7 to 11 are views illustrating the micro device alignment apparatus according to the preferred exemplary embodiment of the present disclosure.

FIGS. 12a to 12f are views sequentially illustrating a transfer method using the micro device alignment apparatus according to the preferred exemplary embodiment of the present disclosure.

### MODE FOR THE INVENTION

The following is merely illustrative of the principles of the present disclosure. Therefore, although not explicitly described or shown herein, those skilled in the art can embody the principles of the present disclosure and devise various devices that are included in the concept and scope of the present disclosure. In addition, it should be understood that all conditional terms and examples listed herein are, in principle, expressly intended only for the purpose of understanding the inventive concept and are not limited to the specifically enumerated exemplary embodiments and states as such.

The above-described objectives, features, and advantages will become more apparent through the following detailed description in conjunction with the accompanying drawings, and accordingly, those skilled in the art to which the present disclosure pertains will be able to easily implement the technical idea of the present disclosure.

The exemplary embodiments described herein will be described with reference to cross-sectional views and/or perspective views, which are ideal illustrative drawings of the present disclosure. The thicknesses of films and regions, and the like shown in these drawings are exaggerated for effective description of technical content. The shape of the illustrative drawing may be modified due to manufacturing technology and/or allowable errors. In addition, only a part of the number of moldings shown in the drawings is exemplarily shown in the drawings. Accordingly, exemplary embodiments of the present disclosure are not limited to the specific form shown, but also include changes in the form generated according to a manufacturing process.

In describing various exemplary embodiments, components that perform the same function will be given the same names and same reference numbers for convenience even though the exemplary embodiments are different from each other. In addition, configurations and operations already described in other exemplary embodiments will be omitted for convenience.

A micro device 10 may include a mini LED or a micro LED. The micro LED is cut out from a wafer used for crystal growth without being packaged with molded resin or the like. One side of the micro device 10 may have a length in a size of 1 to 100 μm. However, the length of one side is not limited to the size of 1 to 100 μm, and has a size greater than or equal to 100 μm, or a size less than 1 μm.

Configurations of a preferred exemplary embodiment of the present disclosure described below may be applied to transfer of micro devices that may be applied without changing the technical idea of each exemplary embodiment.

The micro device 10 according to the preferred exemplary embodiment of the present disclosure is provided for a micro device 10 that has to be aligned with at least any one surface of front and rear surfaces thereof when mounted on a substrate and simultaneously be aligned with any one direction when mounted on the substrate. The substrate herein includes any substrate such as a temporary substrate, a carry substrate, a wiring substrate, a target substrate, and the like.

The micro device 10 is mounted on a wiring substrate 45 so that a display device using the micro device 10 may be manufactured. In this case, the wiring substrate 45 may be provided with a first electrode pad 45a connected to a first terminal 11a of the micro device and a second electrode pad 45b connected to a second terminal 11b of the micro device, the first and second electrode pads being formed in advance. Accordingly, only when the micro device 10 is aligned with at least any one surface of a front surface 10a and rear surface 10b thereof when the micro device 10 is mounted on the wiring substrate 45, and the micro device 10 is simultaneously aligned with any one direction when the micro device 10 is mounted on the wiring substrate 45, it is possible to transfer the micro device 10 without the need for a repair process.

To this end, according to the preferred exemplary embodiment of the present disclosure, in each micro device 10, each top view shape thereof before and after inversion of the front and rear surfaces thereof is not the same shape identical to each other, and simultaneously, each top view shape thereof before and after rotation when rotated 180 degree angles relative to a center point of each micro device 10 is not the same shape identical to each other. Alternately, the top view shape of each micro device 10 is not an overlapping shape when folded along an axis of symmetry thereof, and simultaneously, the top view shape of each micro device 10 is not an overlapping shape when rotated 180 degree angles relative to a central axis thereof. Alternately, the top view shape of each micro device 10 is not a line-symmetrical shape, and simultaneously, the top view shape of each micro device 10 is not a point-symmetrical shape.

The micro device alignment apparatus 100 according to the preferred exemplary embodiment of the present disclosure includes: an alignment part 20 provided with a plurality of receiving parts 21 in which a plurality of micro devices 10 is respectively received, wherein each receiving part 21 is formed in the same shape as the top view shape of each micro device 10. The receiving part 21 may be formed in a shape such that each top view shape thereof before and after inversion of the front and rear surfaces thereof is not the same shape identical to each other, and simultaneously, each top view shape thereof before and after rotation when rotated 180 degree angles relative to a center point of the top view thereof is not the same shape identical to each other. Alternatively, the receiving part 21 may be formed in a shape whose top view shape is not a line-symmetrical shape, and simultaneously whose top view shape is not a point-symmetrical shape. Alternately, the receiving part 21 may be formed in a shape such that the top view shape thereof is not an overlapping shape when folded along the axis of symmetry thereof, and simultaneously, the top view shape thereof is not an overlapping shape when rotated 180 degree angles relative to the central axis thereof.

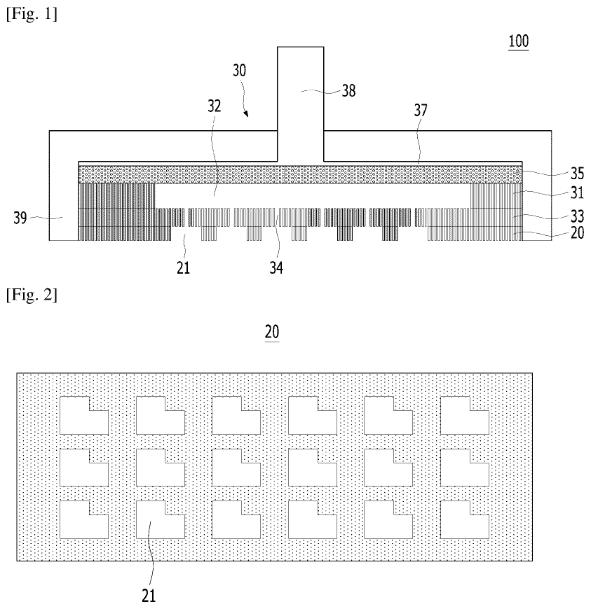

FIG. 1 is a view illustrating a micro device alignment apparatus 100 that is provided with an alignment part 20 according to the preferred exemplary embodiment of the present disclosure and is configured with a picker head 30. The micro device alignment apparatus 100 provided with the alignment part 20 may be provided in the picker head 30 capable of ascending and descending.

Referring to FIG. 1, the micro device alignment apparatus 100 of the present disclosure is configured to include: an alignment part 20 provided with receiving parts 21 respectively corresponding to micro devices 10; and a cavity chamber part 31 provided with a cavity chamber 32 and a vacuum adsorption part 33 provided on an upper part of the alignment part 20 and provided with through-holes 34.

At least one of the alignment part 20, the vacuum adsorption part 33, and the cavity chamber part 31 may be made of an anodized film 10 material. The anodized film refers to a film formed by anodizing a metal as a base material, and pore holes refer to holes formed in a process of forming the anodized film by anodizing the metal. For example, in the case where the metal as the base material is aluminum (Al) or an aluminum alloy, when the base material is anodized, an anodized film made of the aluminum oxide (Al₂O₃) material is formed on a surface of the base material. The anodized film formed as described above is divided into a barrier layer in which no pore holes are formed vertically and a porous layer having the pore holes formed therein. The barrier layer is positioned on an upper part of the base material, and the porous layer is positioned on an upper part of the barrier layer. As such, in the base material having the surface thereof on which the anodized film having the barrier layer and the porous layer are formed, when the base material is removed, only the anodized film made of the aluminum oxide (Al₂O₃) material remains.

The anodized film may be formed in a structure in which the pore holes vertically pass through the anodized film by removing the barrier layer formed during anodization. Alternatively, the barrier layer formed during anodization may remain as it is, and may be formed in a structure that seals one end of upper and lower ends of each pore hole.

The anodized film has a coefficient of thermal expansion of 2 to 3 ppm/° C. For this reason, when exposed to a high temperature environment, thermal deformation caused by the temperature may be small. Since the micro device alignment apparatus 100 according to the preferred exemplary embodiment of the present disclosure should align micro devices having a size greater than or equal to 1 μm and less than or equal to 100 μm, the micro device alignment apparatus should not be sensitively deformed due to the temperature of a surrounding environment. By composing at least one of the alignment part 20, the vacuum adsorption part 33, and the cavity chamber part 31, which constitute the micro device alignment apparatus 100 according to the preferred exemplary embodiment of the present disclosure, with the anodized film material, the thermal deformation of the micro device alignment apparatus 100 may be minimized. As a result, when the micro device alignment apparatus 100 picks up micro devices 10 for transfer, the thermal deformation of the receiving parts 21 may be minimized.

The receiving parts 21 of the alignment part 20 according to the preferred exemplary embodiment of the present disclosure may be respectively formed in recess patterns each having angled corners in order to perform surface alignment and direction alignment of the micro devices 10. Since the alignment part 20 has to align each micro device 10 having a very small size greater than or equal to 1 μm and less than or equal to 100 μm, and has to align tens to millions of micro devices 10 all together at once, the receiving parts 21 should be formed in a method capable of manufacturing the shape of each receiving part 21, in a single step with precision, in a recess pattern having the angled corners. According to the configuration in which the alignment part 20 according to the preferred exemplary embodiment of the present disclosure is formed of an anodized film, a precise recess pattern capable of receiving a micro device 10 having the very small size greater than or equal to 1 μm and less than or equal to 100 μm may be manufactured by using a process of etching the anodized film, and tens of thousands to millions of recess patterns may be manufactured in one etching process. Accordingly, from the standpoint of the alignment part 20, which should have the precise recess patterns each having the angled corners all together at once in order to perform the surface alignment and direction alignment of the micro devices 10, it is preferable to manufacture the alignment part 20 by using the anodized film. In addition, according to the configuration for etching the anodized film, since inner walls of each recess pattern has characteristics of a vertical inner wall, it is preferable in terms of receiving the micro devices 10.

In addition, it is preferable that the vacuum adsorption part 33 is also made of the anodized film material. The vacuum adsorption part 33 is provided with through-holes 34 for adsorbing each micro device 10 by vacuum. Since the number of micro devices 10 to be adsorbed by vacuum at one time is tens of thousands to millions, tens of thousands to millions of through-holes 34 should also be formed. Accordingly, the vacuum adsorption part 33 is formed of the anodized film material is preferable because tens to millions of through-holes 34 may be formed in one etching process. In addition, according to the configuration for etching the anodized film, since the inner walls of each through-hole 34 has the characteristics of the vertical inner wall, the configuration is preferable in terms of vacuum adsorption.

The cavity chamber part 31 is provided with a cavity chamber 32. The cavity chamber part 31 may be formed of a material other than the anodized film, but when the cavity chamber part 31 is composed of the anodized film material, the cavity chamber 32 may be formed by using the etching process. The cavity chamber 32 communicates with at least two or more through-holes 34, thereby minimizing a pressure difference between a plurality of through-holes 34 communicating with each other.

A porous part 35 may be provided on an upper part of the cavity chamber part 31. A porous ceramic material constituting the porous part 35 may be composed of a sintered body made of the porous ceramic material having an arbitrary arrangement in which pores are disordered.

On the upper part of the cavity chamber part 31, the porous part 35 may perform a function of supporting the cavity chamber part 31, the vacuum adsorption part 33, and the alignment part 20. The porous part 35 may be composed of a porous support body having arbitrary pores, and there is no limitation on a material as long as the material may perform the function of supporting the components positioned thereunder.

The porous part 35 may be composed of a rigid porous support body having an effect in preventing sagging of a center thereof. As an example, the sintered body of the porous ceramic material constituting the porous part 35 may be one kind of the material constituting the rigid porous support body. At least one of the cavity chamber part 31, the vacuum adsorption part 33, and the alignment part 20 may be made of the anodized film material. The anodized film material may be provided in the form of a thin film. Accordingly, the porous part 35 may perform a function of preventing a plate made of the anodized film material from being deformed due to air pressure.

The porous part 35 may be composed of a porous buffer. The porous part 35 is not limited in material thereof as long as having a configuration capable of performing the function of buffering the alignment part 20. For example, a porous plate AP may be made of a porous elastic material such as a sponge.

A support part 39 may be provided at the periphery (i.e., upper part and/or side parts) of the porous part 35. The support part 39 may support the porous part 35, the cavity chamber part 31, the vacuum adsorption part 33, and/or the alignment part 20, and preferably the support part 39 supports the porous part 35.

A free space part 37 may be provided between the support part 39 and the porous part 35. The free space part 37 may be connected to a vacuum port for supplying or releasing the air pressure. The porous part 35 is positioned between the free space part 37 and the cavity chamber 32. The porous part 35 may allow the air pressure supplied through a pipe part 38 to be diffused and distributed in the cavity chamber 32 according to the operation of the vacuum port.

The air pressure supplied to the free space part 37 may be transferred to the upper part of the porous part 35. The free space part 37 may communicate over the surface of the upper part of the porous part 35. The porous part 35 may be provided to be spaced apart from the support part 39 by a predetermined distance. The free space part 37 may be formed due to the above spaced distance. For this reason, the air pressure supplied to the free space part 37 may be evenly transferred to the surface of the upper part of the porous part 35. While being equalized by irregular pores formed inside the porous part 35, the air pressure transferred to the porous part 35 may be transferred downward. The equalized air pressure may be transferred to the cavity chamber 32 of the cavity chamber part 31 provided under the porous part 35.

The air pressure transferred to the cavity chamber 32 may be transferred to the through-holes 34 communicating with the cavity chamber 32. For this reason, a vacuum suction force capable of adsorbing the micro devices 10 is formed in the through-holes 34, thereby adsorbing the micro devices 10. The air pressure transferred to the cavity chamber 32 may also be transferred to pore holes existing around the through-holes 34. Since the pore holes are formed in a fine size, a minute vacuum suction force may be formed through the air pressure transferred to the pore holes. The vacuum suction force generated through the pore holes may assist in stable adsorption of the micro devices 10 through the through-holes 34 after the micro devices 10 are adsorbed by the vacuum suction force generated in the through-holes 34. As a result, the micro device alignment apparatus 100 provided with the alignment part 20 may stably transfer the micro devices 10 without the problem that the micro devices 10 are detached during the transfer process of the micro devices 10.

Referring to FIG. 2, the receiving parts 21 provided in the alignment part 20 are formed in a structure in which micro devices 10 may be respectively received therein. Each receiving part 21 may be formed in a shape such that each top view shape thereof before and after inversion of the front and rear surfaces thereof is not the same shape identical to each other, and simultaneously, each top view shape thereof before and after rotation when rotated 180 degree angles relative to the center point of the top view thereof is not the same shape identical to each other. Alternatively, each receiving part 21 may be formed in a shape whose top view shape is not a line-symmetrical shape, and simultaneously whose top view shape is not a point-symmetrical shape. Alternately, each receiving part 21 may be formed in a shape such that the top view shape thereof is not an overlapping shape when folded along the axis of symmetry thereof, and simultaneously, each top view shape thereof is not an overlapping shape when rotated 180 degree angles relative to the central axis thereof.

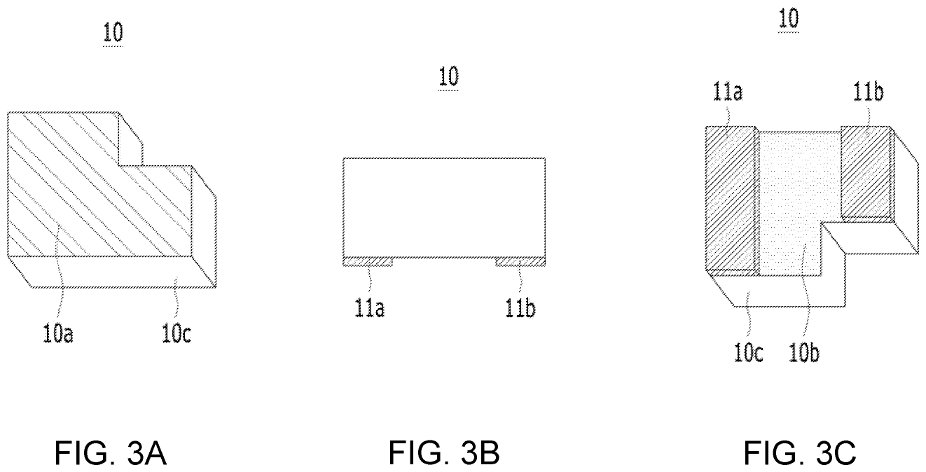

Referring to FIG. 3(a) to 3(c), the micro device 10 is formed in a shape corresponding to the shape of respective receiving part 21, and is formed with a size smaller than the size of the receiving part 21 so as to be received in the receiving part 21. The micro device 10 may be configured to include a front surface 10a, a rear surface 10b, and a side surface 10c.

Both terminals 11a and 11b may be provided on any one surface of the front surface 10a and rear surface 10b of the micro device 10. The micro device 10 may be a flip chip type light-emitting device. The micro device 10 includes a p-type semiconductor layer, an active layer, and an n-type semiconductor layer. A first terminal 11a and a second terminal 11b serve to function as electrodes of each micro device 10, and may be formed on the same surface of each micro device 10 so as to be configured in a flip chip type. For example, the first terminal 11a and the second terminal 11b may be provided on the rear surface 10b of each micro device 10 while being spaced apart from each other, and each micro device 10 may emit light by applying electricity to the first and second terminals 11a and 11b thereof.

The micro devices 10 are transferred to and mounted on the wiring substrate 45 so that the display device using the micro devices 10 may be manufactured. In this case, a first electrode pad 45a connected to the first terminal 11a of each micro device and a second electrode pad 45b connected to the second terminal 11b of each micro device may be formed in advance so as to be provided in the wiring substrate 45. Accordingly, in the case of transferring the micro devices 10 to the wiring substrate 45 by using a transfer device 90, only when each micro device 10 is aligned with any one surface of the front surface 10a and rear surface 10b thereof, and the first terminal 11a and second terminal 11b thereof are aligned with any one direction, it is possible to mount the micro devices 10 without the need for the repair process.

When the micro devices 10 are respectively received in the receiving parts 21 of the alignment part 20, it is configured such that each micro device 10 has an top view shape thereof and each receiving part 21 is also formed with a recess having the same shape as the top view shape of each micro device 10, so that in consideration of directions of the first and second terminals 11a and 11b of each micro device 10, each of the micro devices 10 is aligned with at least any one surface of the front surface 11a and rear surface 11b thereof, and simultaneously is aligned with any one direction. Each micro device 10 may be formed to have a specific top view shape through the etching process after being manufactured on a growth substrate.

Preferably, each micro device 10 may be formed in a shape such that each top view shape thereof before and after inversion of the front and rear surfaces thereof is not the same shape identical to each other, and simultaneously, each top view shape thereof before and after rotation when rotated 180 degree angles relative to the center point of the top view is not the same shape identical to each other. Here, the fact that top view shapes have the same shape identical to each other includes a meaning that the top view shapes have the same area size.

Alternatively, the micro device 10 may be formed in a shape whose top view shape is not a line-symmetrical shape, and simultaneously whose top view shape is not a point-symmetrical shape.

Alternately, each micro device 10 may be configured in a shape such that the top view shape thereof is not an overlapping shape when folded along an axis of symmetry thereof, and simultaneously, the top view shape thereof is not an overlapping shape when rotated 180 degree angles relative to the central axis thereof.

Here, the fact that each micro device does not have the same shape identical to each other, do not have a symmetrical shape, or have an overlapping shape includes a meaning that there is a difference in size within a range in which the surface alignment and direction alignment may be performed.

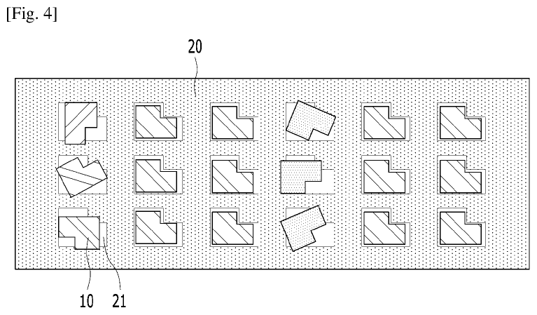

Referring to FIG. 4, the micro devices 10 respectively received in the receiving parts 21 of the alignment part 20 are micro devices 10 in which surface alignment and direction alignment are performed, and the micro devices 10 not respectively received in the receiving parts of the alignment part 20 are micro devices 10 in which any one of the surface alignment and direction alignment is not properly performed. In FIG. 4, expressions of the first and second terminals 11a and 11b are omitted. In FIG. 4, the micro devices 10 positioned in the first row are micro devices 10 that are not respectively received in the receiving parts 21 because direction alignment is not properly performed. In FIG. 4, the micro devices 10 positioned in the fourth row are micro devices 10 that are not respectively received in the receiving part 21 because surface alignment is not properly performed. In FIG. 4, the micro devices 10 positioned in rows 2, 3, 5, and 6 are micro devices 10 respectively received in the receiving parts 21, meaning that the surface alignment and direction alignment are performed. Only the micro devices 10 in which the surface alignment and direction alignment are performed are respectively received in the receiving parts 21 of the alignment part 20. As such, the micro devices 10 respectively received in the receiving parts 21 of the alignment part 20 are the micro devices 10 in which the surface alignment and direction alignment are performed, and thus the micro devices 10 in which the surface alignment and direction alignment are performed in the alignment part 20 may be transferred to the next step.

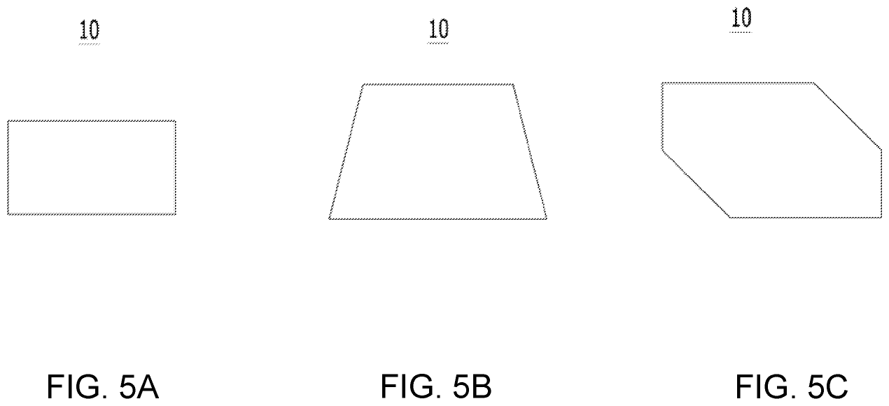

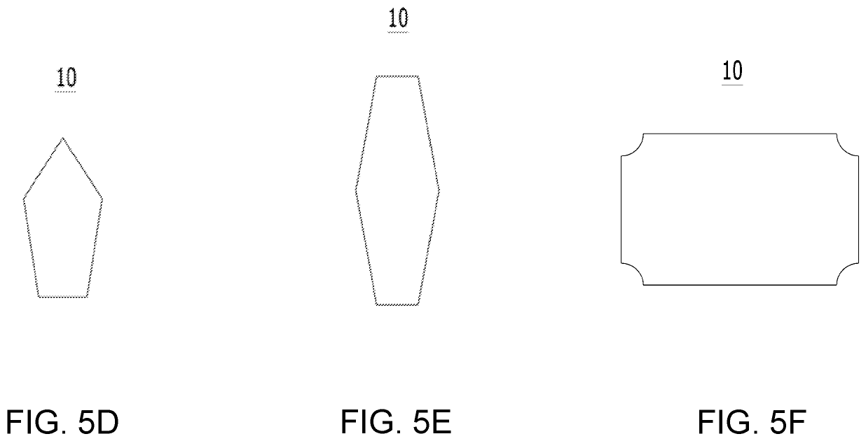

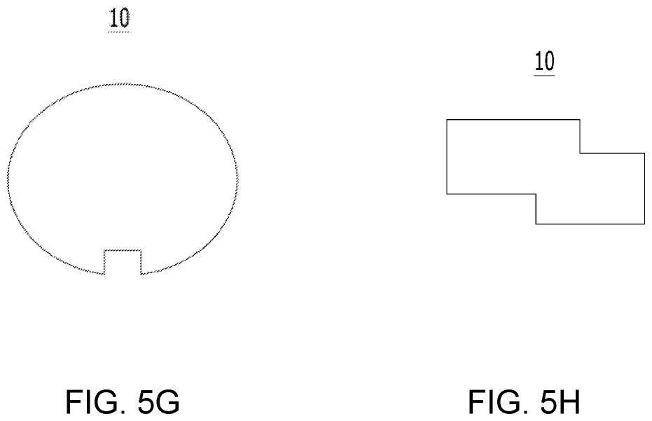

Referring to FIGS. 5(a) to 5(h), the micro devices 10 shown in FIGS. 5(a) to 5(h) are micro devices 10 in which any one of surface alignment and direction alignment is unable to be performed. First, when the top view shape of each micro device 10 has a regular polygonal shape or circular shape, even when the micro devices 10 are respectively received in the receiving parts 21, since the surface alignment and direction alignment are unable to be performed all together at once, the corresponding micro devices 10 should be excluded.

The micro devices 10 shown in FIGS. 5(a), 5(b), 5(e), and 5(f) are micro devices 10 in which the surface alignment and direction alignment are unable to be performed. The micro devices 10 shown in FIGS. 5(a), 5(b), 5(e), and 5(f) has a shape such that each top view shape thereof before and after inversion of the front and rear surfaces thereof is the same shape identical to each other, and simultaneously, each top view shape thereof before and after rotation when rotated 180 degree angles relative to the center point of the top view is the same shape identical to each other. Alternatively, the micro device 10 has a shape in which the top view shape thereof is an overlapping shape when folded along an axis of symmetry thereof, and the top view shape thereof is an overlapping shape when rotated 180 degree angles relative to a central axis thereof. Alternatively, the micro device 10 has the shape in which the top view shape thereof is the line-symmetrical shape, and the top view shape thereof is the point-symmetrical shape. Even when the micro devices 10 having such a shape are respectively received in the receiving part 21, since the surface alignment and direction alignment are unable to be performed all together at once, the corresponding micro devices 10 should be excluded.

The micro devices 10 shown in FIGS. 5(c) and 5(h) are micro devices 10 in which the direction alignment is unable to be performed. When the micro devices 10 shown in FIGS. 5(c) and 5(h) are rotated 180 degree angles relative to the center point of the plan view thereof, each plan view shape before and after rotation is the same shape identical to each other. Alternatively, each micro device 10 has an overlapping shape when the top view shape thereof is rotated 180 degree angles relative to the center point thereof. Alternatively, each micro device 10 has a point-symmetrical shape in the plan view shape thereof. Even when the micro devices 10 having such a shape are respectively received in the receiving parts 21, since the directions of the first and second terminals 11a and 11b of each micro device 10 are not uniform, the direction alignment is unable to be performed, whereby the corresponding micro devices 10 should be excluded.

The micro devices 10 shown in FIGS. 5(d) and 5(g) are micro devices 10 in which the surface alignment is unable to be performed. The micro devices 10 shown in FIGS. 5(d) and 5(g) have a shape such that each top view shape thereof before and after inversion of the front and rear surfaces thereof is the same shape identical to each other. Alternatively, each micro device 10 has an overlapping shape when the top view shape thereof is folded along the axis of symmetry thereof. Alternatively, each micro device 10 has a line-symmetrical shape in the plan view shape thereof. Even when the micro devices 10 having such a shape are respectively received in the receiving parts 21, since the surfaces on which the first and second terminals 11a and 11b of each micro device 10 are provided are not uniformly aligned, the surface alignment is unable to be performed, whereby the corresponding micro devices 10 should be excluded.

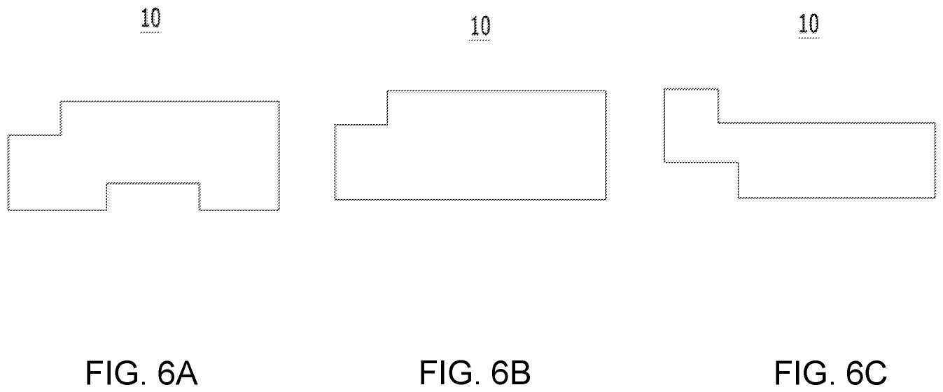

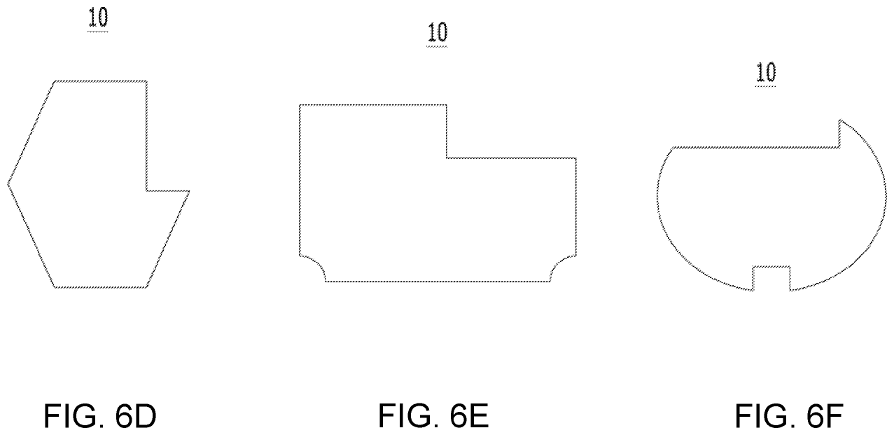

Referring to FIGS. 6(a) to 6(f), the micro devices 10 shown in FIGS. 6(a) to 6(f) are the micro devices 10 in which the surface alignment and direction alignment may be performed when the micro devices 10 are respectively received in the receiving parts 21 of the alignment part 20. The micro devices 10 shown in FIGS. 6(a) to 6(f) have a shape such that each top view shape thereof before and after inversion of the front and rear surfaces thereof is not the same shape identical to each other, and simultaneously, each top view shape thereof before and after rotation when rotated 180 degree angles relative to the center point of the top view is not the same shape identical to each other. Alternatively, each micro device 10 has a shape whose top view shape is not a line-symmetrical shape, and simultaneously whose top view shape is not a point-symmetrical shape. Alternately, the micro devices 10 has a shape in which the top view shape thereof is not an overlapping shape when folded along the axis of symmetry thereof, and simultaneously, the top view shape thereof is not an overlapping shape when rotated 180 degree angles relative to the center point thereof. When the micro devices 10 having such a shape are respectively received in the receiving parts 21, the directions and the surfaces on which the first and second terminals 11a and 11b of each micro device 10 are provided may be uniformly aligned. In other words, in the micro devices 10 respectively received in the receiving parts 21, the surface directions thereof are uniformly aligned with any one of the surface provided with the first and second terminals 11a and 11b or the opposite surface thereof, and the directions are uniformly aligned so that the directions of the terminals 11a and 11b are all in the same direction.

A method of aligning micro devices 10 according to the preferred exemplary embodiment of the present disclosure includes: (i) preparing a plurality of micro devices 10, in a non-aligned state, that is not aligned with at least any one surface of the front surface 10a and the rear surface 10b and simultaneously is not aligned in any one direction; and (ii) allowing the micro devices 10 to be respectively received in receiving parts 21 by using alignment part 20 provided with a plurality of receiving parts 21 capable of respectively receiving the plurality of micro devices 10, and performing surface alignment and direction alignment wherein the micro devices 10 respectively received in the receiving parts 21 are aligned with at least any one of the front surface 10a and the rear surface 10b of each micro device and simultaneously directions of the micro devices 10 are aligned with any one direction of each micro device.

The preparing of the plurality of micro devices 10 in the non-aligned state may be performed only for good quality micro devices 10. In the preparing of the plurality of micro devices 10 in the non-aligned state, the plurality of micro devices 10 may be provided in the non-aligned state on a support substrate 50, or the plurality of micro device 10 may be provided in the non-aligned state on a surface or inside of a fluid.

The preparing of the plurality of micro devices 10 in the non-aligned state has an advantage in that non-uniformity of light-emitting characteristics of the micro devices 10 may be resolved, only the good quality micro devices 10 may be used, a separate process for uniformization is not required, and the need for the repair process is eliminated.

Specifically, micro devices 10 manufactured on a growth substrate do not have the uniform light-emitting characteristics such as luminance. In a case where the micro devices 10 are transferred to the wiring substrate 45 while the arrangement of the micro devices 10 manufactured on the growth substrate is maintained, the luminance of the display device also reflects the luminance distribution in the growth substrate, so there occurs a problem that the overall luminance distribution becomes non-uniform. Accordingly, in the preparing of the plurality of micro devices 10 in the unaligned state, it is preferable that the arrangement on the growth substrate is not followed as it is and is in a disordered state.

In addition, the micro devices 10 manufactured on the growth substrate may include defective products during a manufacturing process. When such defective products are not removed, a process for repairing the defective products is required during the process of transferring the micro devices to the wiring substrate 45 or in a process after the transferring of the micro devices to the wiring substrate 45. Accordingly, in the preparing of the plurality of micro devices 10 in the non-aligned state, it is preferable to target only the micro devices 10 determined to have good quality through an inspection step after being manufactured on the growth substrate.

The alignment step in which the directions are aligned is a step in which the surface alignment and direction alignment are performed for the plurality of micro devices 10 in the non-aligned state, and may be performed by using the micro device alignment apparatus 100 that includes the alignment part 20 provided with the receiving parts 21.

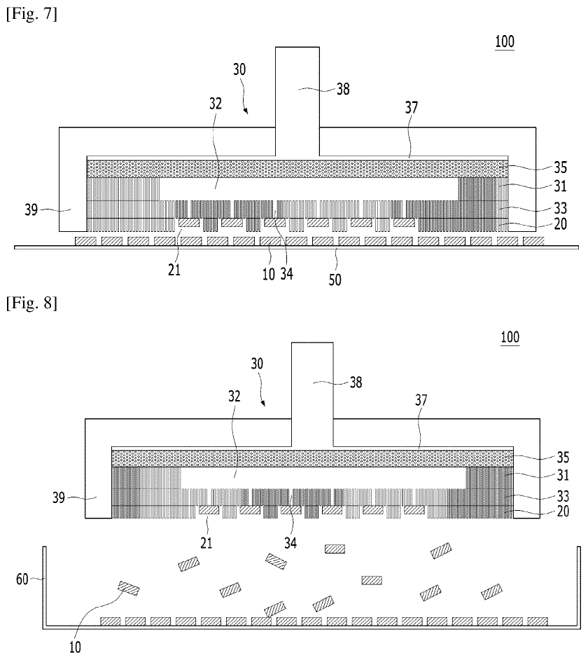

Referring to FIG. 7, the micro device alignment apparatus 100 includes a picker head 30. The alignment part 20 may be provided in the picker head 30 capable of ascending and descending. Here, the alignment part 20 and each micro device 10 have a configuration in which the surface alignment and direction alignment of the micro devices 10 are performed when the micro devices 10 are respectively received in the receiving parts 21 of the alignment part 20.

The picker head 30 may be provided with a structure that enables the picker head 30 to be raised and lowered, to be rotatable, and to be horizontally moved. The micro devices 10 may be positioned on a support substrate 50. Here, the support substrate 50 is not limited in shape and material thereof as long as the support substrate 50 is a member performing a function of supporting the micro devices 10. The micro devices 10 positioned on the support substrate 50 may be non-aligned micro devices 10 having good quality.

While performing at least any one of ascending, descending, rotation, and horizontal movement one-time, repeatedly, or sequentially, the picker head 30 causes the micro devices 10 to be respectively received in the receiving parts 21 of the alignment part 20 by a vacuum suction force. In this way, only the micro devices 10 in which the surface alignment and direction alignment may be performed are respectively received in the receiving parts 21 of the alignment part 20, and the micro devices 10 in which the surface alignment and direction alignment are unable to be performed are not respectively received in the receiving parts 21.

As such, since the micro devices 10 adsorbed to the picker head 30 are micro devices 10 with the surface alignment and direction alignment completed, it is possible to mount the micro devices 10 that do not require the repair process when mounted on the wiring substrate 45.

Referring to FIG. 8, the micro device alignment apparatus 100 includes a receiving chamber 60. The plurality of micro devices 10 having good quality are received in the receiving chamber 60. At a distance spaced apart from the bottom of the receiving chamber 60, the picker head 30 adsorbs the micro devices 10. Here, the spaced distance is a distance in which the micro devices 10 may be adsorbed to the picker head 30 after the micro devices 10 are floated to a predetermined height from the bottom of the receiving chamber 60 by the vacuum suction force of the picker head 30. Even in this case, while performing at least any one of ascending, descending, rotation, and horizontal movement one-time, repeatedly, or sequentially, the picker head 30 may cause the micro devices 10 to be respectively received in the receiving parts 21 of the alignment part 20 by the vacuum suction force.

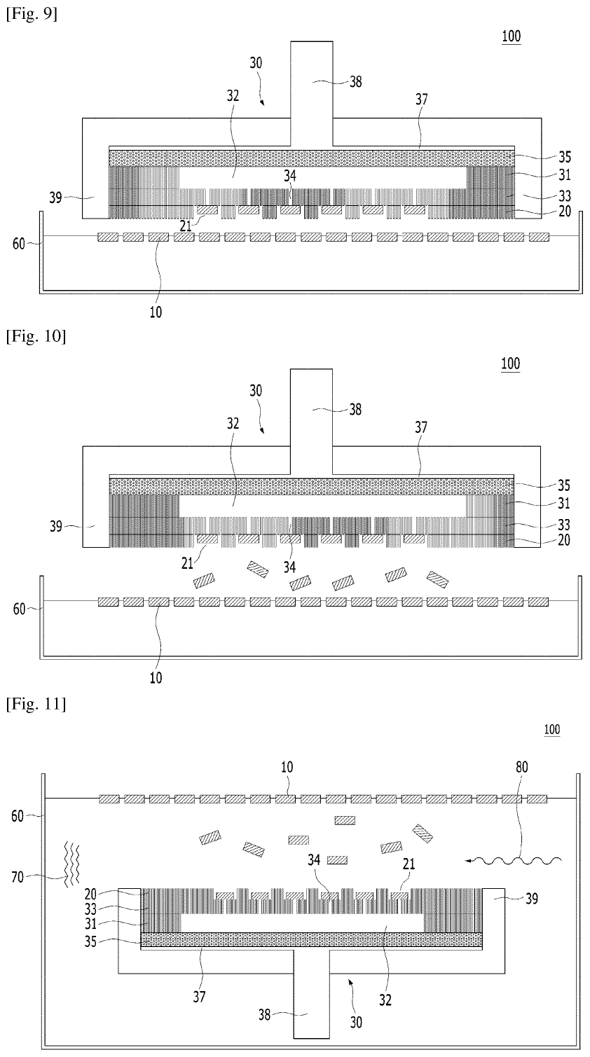

Referring to FIG. 9, the micro device alignment apparatus 100 includes the receiving chamber 60 in which a fluid is accommodated. The fluid includes water, but is not limited thereto. The specific gravity of the fluid may be adjustable, and the micro devices 10 may be treated with a surface hydrophilic treatment or surface hydrophobic treatment. The good quality micro devices 10 are put into the receiving chamber 60. The micro devices 10 become a non-aligned state due to the fluid. Due to a difference in specific gravity with the fluid, at least a portion of the micro devices 10 may be floated, by the fluid, on the surface of the fluid. In such a state, while performing at least any one of ascending, descending, rotation, and horizontal movement one-time, repeatedly, or sequentially, the picker head 30 may cause the micro devices 10 to be respectively received in the receiving parts 21 of the alignment part 20 by the vacuum suction force.

Referring to FIG. 10, the picker head 30 adsorbs the micro devices 10 at a distance spaced apart from the surface of the fluid of the receiving chamber 60. Here, the spaced distance is the distance in which the micro devices 10 may be adsorbed to the picker head 30 after the micro devices 10 are floated to the predetermined height from the surface of the fluid by the vacuum suction force of the picker head 30. Even in this case, while performing at least any one of ascending, descending, rotation, and horizontal movement one-time, repeatedly, or sequentially, the picker head 30 may cause the micro devices 10 to be respectively received in the receiving parts 21 of the alignment part 20 by the vacuum suction force.

Referring to FIG. 11, the picker head 30 may be positioned inside the fluid of the receiving chamber 60. Even in this case, while performing at least any one of ascending, descending, rotation, and horizontal movement one-time, repeatedly, or sequentially, the picker head 30 may cause the micro devices 10 to be respectively received in the receiving parts 21 of the alignment part 20.

A vibration generation part 70 may be provided in the receiving chamber 60 in which the fluid is accommodated. The vibration generation part 70 may apply vibration to the fluid. As long as the vibration generation part 70 is a means, including an ultrasonic vibrator, capable of applying vibration to the fluid, there is no limitation thereto.

In this way, it may be allowed that the aggregation between the micro devices 10 that are clustered together in the receiving chamber 60 is dismantled, or the surfaces and/or directions of the micro devices 10 are changed. In addition, the micro devices 10 may be more easily, respectively received in the receiving parts 21 of the alignment part 20 by applying vibration to the fluid through the vibration generation part 70.

A flow generation part 80 may be provided in the receiving chamber 60 in which the fluid is accommodated. The flow generation part 80 is configured to generate a flow in the fluid in the receiving chamber 60 by including a fluid injector or a fluid inhaler. Through the flow generation part 80, the micro devices 10 are not positioned in any one particular direction, but are allowed to move in the fluid, to change directions thereof, or to change surfaces thereof. In addition, when each micro device 10 is not properly received in the respective receiving part 21 and is in a caught state, it is possible to induce complete reception through the flow generation part 80 or to be removed from the periphery of each receiving part 21.

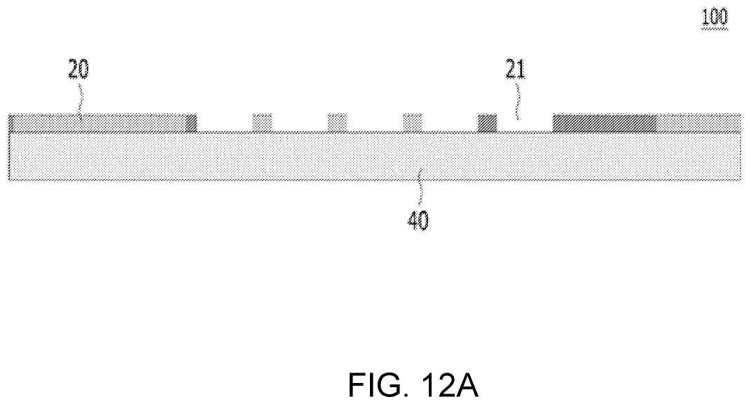

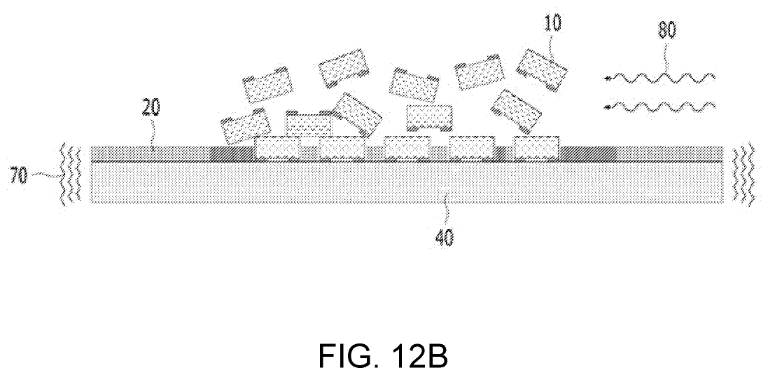

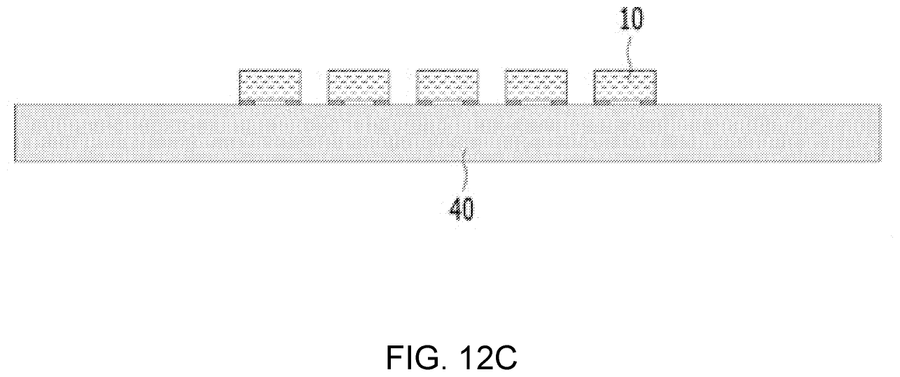

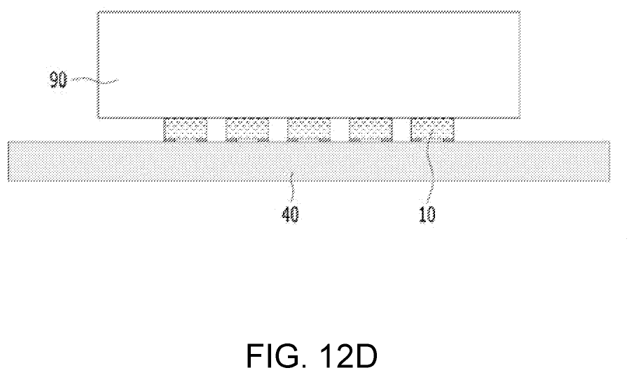

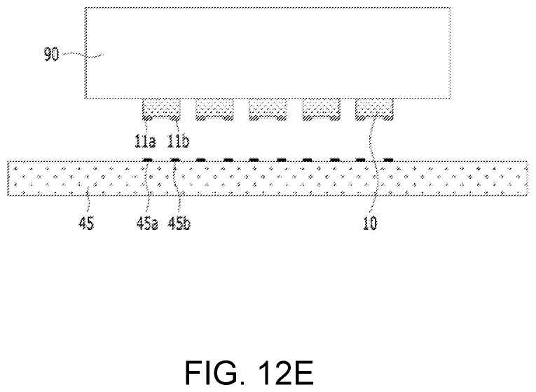

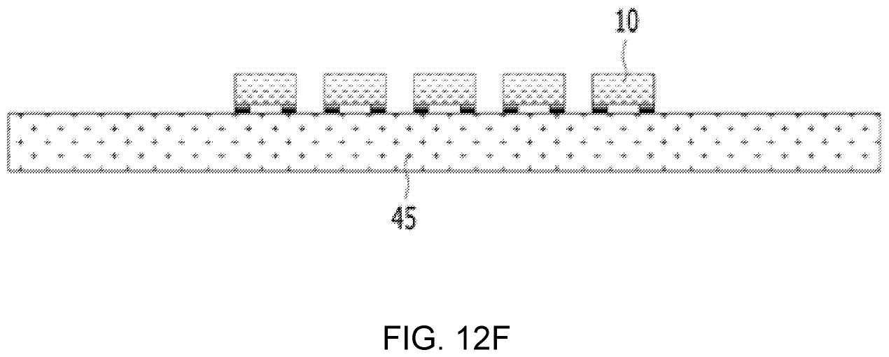

Referring to FIGS. 12a to 12f, the micro device alignment apparatus 100 is configured to include the alignment part 20 provided on a temporary substrate 40. Referring to FIG. 12a, the alignment part 20 is provided on the temporary substrate 40. The alignment part 20 is seated on the temporary substrate 40. The temporary substrate 40 has an adsorption force for the micro devices 10. The adsorption force includes an electrostatic force, a vacuum suction force, a van der Waals force, and the like, and when a magnetic material is provided in each micro device 10, the adsorption force includes a magnetic force. The alignment part 20 may be provided to be movable relative to the temporary substrate 40. By moving the alignment part 20 relative to the temporary substrate 40 vertically or horizontally, each micro device 10 that is not properly received in the respective receiving part 21 of the alignment part 20 and is caught on the receiving part 21 is allowed to be received into the receiving part 21.

Referring to FIG. 12a, the alignment part 20 is seated on the temporary substrate 40. Thereafter, as shown in FIG. 12b, the micro devices 10 are inserted and placed above the alignment part 20. It may be configured such that each of the micro devices 10 is only a good quality micro device 10. The micro devices 10 respectively received in the receiving parts 21 are micro devices 10 in which the surface alignment and direction alignment are performed. Vibration may be applied to the temporary substrate 40 and/or the alignment part 20 by using the vibration generation part 70, so that each micro device 10 may be more easily received in the respective receiving part 21. Alternatively, air is injected or exhausted through the flow generation part 80 so that each micro device 10 may be more easily received in the respective receiving part 21.

Referring to FIG. 12c, in order to prevent interference between the alignment part 20 and the transfer device 90, the alignment part 20 may be separated from the temporary substrate 40 and removed therefrom. However, when the alignment part 20 does not interfere with the transfer device 90, the alignment part 20 may be positioned on the temporary substrate 40 as it is, which should make no difference.

Referring to FIG. 12d, the transfer device 90 adsorbs the micro devices 10 by using the adsorption force. Here, the adsorption force includes the electrostatic force, vacuum suction force, van der Waals force, and the like, and when the magnetic material is provided in each micro device 10, the adsorption force includes the magnetic force.

Referring to FIG. 12e, the transfer device 90 transfers the micro devices 10 to the wiring substrate 45 provided with the first electrode pad 45a and the second electrode pad 45b. The wiring substrate 45 is provided with the first electrode pad 45a connected to the first terminal 11a of a micro device 10, and is provided with the second electrode pad 45b connected to the second terminal 11b of the micro device 10.

Referring to FIG. 12f, since the micro devices 10 adsorbed to the transfer device 90 have already completed the surface alignment and direction alignment, additional alignment is not required when the micro devices 10 adsorbed to the transfer device 90 are mounted on the wiring substrate 45.

As described above, according to the preferred exemplary embodiment of the present disclosure, when mounted on the substrate such as the wiring substrate or the carrier substrate, the micro devices may be aligned with at least any one of the front and rear surfaces, and simultaneously the micro devices are aligned with any one direction.

As described above, although the present disclosure has been described with reference to the preferred exemplary embodiment, those skilled in the art may implement the present disclosure by various modifications or variations within the scope without departing from the spirit and scope of the present disclosure as set forth in the following claims.

### DESCRIPTION OF THE REFERENCE NUMERALS IN THE DRAWINGS

10: micro device 20: alignment apparatus
30: picker head 40: temporary substrate

1. (canceled)

2. (canceled)

3. (canceled)

4. (canceled)

5. A micro device alignment apparatus comprising:
an alignment part provided with a plurality of receiving parts configured to respectively receive a plurality of micro devices,
wherein each receiving part is formed in a same shape as a top view shape of the micro device, and
the top view shape of each receiving part is configured not to be an overlapping shape when folded along an axis of symmetry thereof, and simultaneously the top view shape of each receiving part is configured not to be an overlapping shape when rotated 180 degree angles relative to a center point thereof.

6. The micro device alignment apparatus of claim 5, wherein the alignment part is composed of an anodized film formed by anodizing a metal.

7. The micro device alignment apparatus of claim 5, wherein the alignment part is provided in a picker head capable of ascending and descending.

8. The micro device alignment apparatus of claim 5, wherein the alignment part is provided to be movable relative to a temporary substrate.

9. The micro device alignment apparatus of claim 5, wherein each micro device is a light-emitting device comprising both of two terminals provided on any one surface of front and rear surfaces of each micro device.

10. A micro device alignment apparatus comprising:
an alignment part provided with a plurality of receiving parts configured to respectively receive a plurality of micro devices,
wherein each receiving part is formed in a same shape as top view shapes of each micro device, and in each micro device, each top view shape thereof before and after inversion of the front and rear surfaces thereof is not the same shape identical to each other, and simultaneously, each top view shape thereof before and after rotation when rotated 180 degree angles relative to a center point of each micro device is not the same shape identical to each other.

11. A micro device alignment apparatus configured to perform surface alignment and direction alignment for a plurality of micro devices not aligned with at least any one surface of front and rear surfaces and simultaneously not aligned with any one direction, the micro device alignment apparatus comprising:
an alignment part provided with a plurality of receiving parts configured to respectively receive a plurality of micro devices,
wherein the micro devices respectively received in the receiving parts are aligned with at least any one surface of the front and rear surfaces thereof, and simultaneously directions of terminals of each micro device are aligned in any one direction.

12. The micro device alignment apparatus of claim 11, wherein, in each micro device, each top view shape thereof before and after inversion of the front and rear surfaces thereof is not a same shape identical to each other, and simultaneously, each top view shape thereof before and after rotation when rotated 180 degree angles relative to a center point of each micro device is not the same shape identical to each other.

13. The micro device alignment apparatus of claim 11, wherein one of the front and rear surfaces of the micro device is either a surface on which the terminals of each micro device are provided or a surface opposite to the surface.

14. (canceled)

15. (canceled)
